(19) United States
(12) Patent Application Publication
(10) Pub. No.: US 2021/0232718 A1
(43) Pub. Date: Jul. 29, 2021

(54) Method and system for human centered design implementation

(71) Applicant: Arch Systems, LLC, Baltimore, MD (US)

(72) Inventor: Vini Ehsan, Baltimore, MD (US)

(21) Appl. No.: 16/775,745

(22) Filed: Jan. 29, 2020

(51) Int. Cl. G06F 30/12

(52) U.S. Cl. CPC G06F 30/12; G06N 5/04

(57) ABSTRACT

An end-to-end platform that will incorporate all phases and several methods for conducting Human Centered Design (HCD). The phases included in the platform are: observation, ideation, rapid prototyping, user feedback, iterative improvements, and implementation. The modular, scalable, and extensible platform will include an integrated platform for designing digital and non-digital systems or products using Human Centered Design.

### BACKGROUND OF THE INVENTION

### 1. Field of the Invention

The present invention relates to the field of digital services, systems and product development. More particularly, it relates to methods of systems and product development using the Human Centered Design approach. However, HCD is useful for any type of design. For example, HCD becomes highly useful in policy development policies, help desk functions, and any other solutions where humans are involved.

### 2. Description of the Prior Art

Human-centered design (HCD) is a term system and product designers use to describe a process of designing for people. HCD develops solutions to problems by involving the human perspective in all steps of the problem-solving process. Human-centered design is an approach to interactive systems and product development that aims to make systems usable and useful by focusing on the users, their needs and requirements, and by applying human factors/ergonomics, usability knowledge, and techniques. This approach enhances effectiveness and efficiency, improves human well-being, user satisfaction, accessibility, and sustainability; and counteracts possible adverse effects of use on human health, safety and performance.

Human involvement typically takes place in observing the problem within context, brainstorming, conceptualizing, developing, and implementing the solution. These steps, in some form or fashion, are a fundamental part of the HCD concept. At the heart of it, human-centered design is a problem-solving approach that incorporates end users throughout the design process, to ensure solutions are tailored and suit consumer need.

United States Patent Application 20030177047 discloses a platform for efficiently engineering systems. The method uses a uniquely defined decision model to lead the design effort by structuring and analyzing decision making needs of the people who will use the system before any development efforts can constrain the solution. This consolidated platform includes several methods and methodologies to perform HCD within a specific context, namely, designing digital solutions.

While the above described application may be satisfactory for its intended task, it suffers from the drawback that the various “tools” needed to implement, the HCD are not available from a single consolidated and integrated platform. For example, a key aspect of HCD is that user feedback is employed to tailor a product or system. If the designer must hunt to find the sources of useful feedback such as surveys, emails, software development tools etc., it can make deploying the HCD concept unwieldy and inefficient.

Accordingly, it would be desirable to provide a HCD platform that provides, assembles, and coordinates the various tools and resources needed to implement digital and non-digital system or product design.

In accordance with the above, the present inventive system is an end-to-end platform that will incorporate all phases and several methods for conducting HCD. The phases included in the platform are: observation, ideation, rapid prototyping, user feedback, iterative improvements, and implementation. The modular, scalable, and extensible platform will include a platform for designing systems or products using

Human Centered Design.

### SUMMARY OF THE INVENTION

It is a major object of the invention to provide a platform to effect Human Centered Design (HCD).

It is another object of the invention to provide a platform to effect HCD which is comprehensive and modular.

It is another object of the invention to provide a platform to effect HCD which includes a module for each aspect of HCD modular, scalable, and extensible platform for various phases and methods to perform HCD.

It is another object of the invention to provide a platform to effect HCD which is adaptable with further evolving needs.

It is another object of the invention to provide a platform to effect HCD which employs artificial intelligence to learn and adapt based on user behavior and feedback.

### DETAILED DESCRIPTION OF THE PREFERRED EMBODIMENTS

HCD is a process which essentially uses user feedback and behaviors to enhance the usability of a system or device. The users, in the context of HCD, are the target group and all stakeholders for the product or service being created by the designers. The following steps are generally considered a part of any HCD process:
Observation
Ideation
Rapid prototyping
User feedback
Iterative Improvements
Implementation.

In accordance with a key aspect of the invention, each aspect of this process is addressed by a “module” or component designed to streamline the HCD process. Each module is a software component or program designed to more efficiently practice the HCD process. The system of the invention is to be primarily implemented by software which can be implemented on microprocessor-based end devices, which software will assist designers (as opposed to users). Accordingly, the modules are essentially software applications that can be implemented on designer end devices such as laptops.

The modular, scalable, and extensible system of the invention will include modules for user research, feedback from interviews, surveys and other social interactions, communication and collaboration among users, developer voices, open source community, and United States Digital Services(USDS) feedback, UI/UX design capabilities, and integration within DevSecOps environments. While there are disparate tools in the market, they do not exist in one integrated platform. Government agencies and commercial entities currently use a host of HCD manual tools, email, survey, and collaboration tools, and UI/UX design software to conceptualize and design technical and non-technical solutions within a multi-stakeholder environment. For each phase of the HCD process a designer must be able to quickly access these tools, and there may even be a learning curve associated with the use of these tools.

With respect to the Observation phase for example, research in this stage could include interviews, and, when necessary, field experts. You can also conduct field inquiries and other types of research. With the inventive system a module is provided to streamline this process. Specifically, a designer in the Observation phase using the method of the invention, would access his/her device and initialize the Observation module. The Observation module would then direct the designer to all of the resources necessary to effect the observation stage. This would eliminate the need for each designer to locate the best resources or methods to affect this stage of the HCD process.

When the designer moves on to the next phase of the process, he employs a module designed to specifically implement it. For example, user feedback generally involves locating a target group, inquiring as to, e.g., the efficacy of a certain device, getting responses, and storing and analyzing the responses. With the system of the invention, the designer would simply access a software module on his device, which module will assist with each aspect of the stage of the process so that the user may spend more time analyzing and designing as opposed to tracking down users or collating responses.

The process of accessing successive, targeted modules is continued until the design is complete. In accordance with another key aspect of the invention, the inventive system is adaptive. AI or machine learning is employed to enhance the effectiveness of the modules based on data collected by the platform on an ongoing basis. Specifically, designer feedback and behavior are factored in and the software of the inventive system modifies the modules to increase efficiency of the overall system.

It is to be understood that the present invention is not limited to the sole embodiment described above, but encompasses any and all embodiments within the scope of the following claims:

I claim:

1. A system for implementing human centered design, the system allowing one or more designers using microprocessor based devices to streamline the design of a digital or non-digital product or system, the system comprising:
a plurality of modules, each module specifically designed for a particular phase of HCD, wherein each module is modified by way of artificial intelligence in response to designer input and behavior.
